(19) United States
(12) Patent Application Publication
(10) Pub. No.: US 2025/0221275 A1
(43) Pub. Date: Jul. 3, 2025

(54) DISPLAY APPARATUS

(71) Applicant: LG Display Co., Ltd., Seoul (KR)

(72) Inventors: Byung June MUN, Paju-si (KR); Jung Seop YOON, Paju-si (KR)

(21) Appl. No.: 18/740,114

(22) Filed: Jun. 11, 2024

(30) Foreign Application Priority Data
Dec. 29, 2023 (KR) 10-2023-0197485

(51) Int. Cl. H10K 59/80; H10K 59/122; H10K 59/40

(52) U.S. Cl. CPC H10K 59/879; H10K 59/122; H10K 59/40

(57) ABSTRACT

Embodiments of the present disclosure relates to a display device including a plurality of subpixels, each of the plurality of subpixels including a first light emitting area and a second light emitting area, a first planarization layer, a second planarization layer on the first planarization layer, and is open in an area overlapping the first light emitting area, and includes a first portion inclined while overlapping with the second light emitting area and a second portion surrounding the first portion, a bank layer on the second planarization layer and is open in the first light emitting area, and a lens on the bank layer and disposed to at least partially overlap with an area including the first portion. According to embodiments of the present disclosure, it is possible to reduce or minimize the decrease in luminance of the display device while providing a function to limit the viewing angle.

### CROSS REFERENCE TO RELATED APPLICATION

This application claims priority from Korean Patent Application No. 10-2023-0197485, filed on Dec. 29, 2023, which is hereby incorporated by reference for all purposes as if fully set forth herein.

### BACKGROUND

### Technical Field

The present disclosure relates to a display device, more particularly, relates to a display device capable of increasing light extraction efficiency.

### Description of the Related Art

A light emitting display device (OLED) is a self-emitting display device, and unlike a liquid crystal display device (LCD), the light emitting display does not require a separate light source and can be manufactured in a lightweight and thin form. In addition, light emitting display devices are not only advantageous in terms of power consumption due to low voltage operation, but also have excellent color reproduction, response speed, viewing angle, and contrast ratio (CR), and are being studied as next-generation display devices.

The light emitting display devices may be used in a variety of places. Accordingly, users may selectively limit the viewing angle to prevent the display screen from being exposed to people around, and various technologies are being used to limit the viewing angle.

As some of the light emitted from a light emitting layer may be absorbed inside the light emitting display device, there may be problems that the luminance of the display device decreases and light extraction efficiency decreases. Accordingly, the inventors of the present disclosure propose a display device capable of preventing a decrease in luminance of a light emitting display device and increasing light extraction efficiency while limiting the viewing angle.

### BRIEF SUMMARY

Embodiments of the present disclosure may provide a display device capable of reducing or minimizing a decrease in luminance of the display device due to light emitted from a light emitting layer being trapped inside a display device.

Embodiments of the present disclosure may provide a display device capable of increasing a light extraction efficiency of the display device.

The problems to be solved according to an embodiment of the present disclosure are not limited to the problems as above, and another problems may be clearly understood by those skilled in the art from the description below.

According to an embodiment of the present disclosure, there may be provided a display device capable of preventing a decrease in luminance. A first planarization layer may be formed on a substrate. A second planarization layer may be formed on the first planarization layer. The second planarization layer may include at least one opening area, and may include at least a portion having an inclined surface around the opening area. A bank layer may be formed on the second planarization layer. A lens may be formed on the bank layer. The lens may be disposed to at least partially overlap an area including the portion having the inclined surface.

A display device according to embodiments of the present disclosure may have an effect of reducing or minimizing a decrease in the luminance of the display device.

In addition, there may have an effect of increasing the light extraction efficiency.

In addition, according to the embodiments of the present disclosure, there may provide a display device capable of low power consumption by increasing light extraction efficiency.

The effects of the present disclosure are not limited to the effects described above, and other effects not described will be clearly understood by those skilled in the art from the description below.

### BRIEF DESCRIPTION OF THE SEVERAL VIEWS OF THE DRAWINGS

FIG. 1 illustrates an example of the structure of a display device and a circuit structure included in a subpixel according to embodiments of the present disclosure.

FIGS. 2A and 2B are diagrams illustrating an example of a planar structure of a display device according to embodiments of the present disclosure.

FIG. 3 illustrates an example of the cross-sectional structure of a part I-I′ shown in FIG. 2.

FIG. 4 is an enlarged view of part A of FIG. 3.

FIGS. 5A and 5B are diagrams illustrating another example of a planar structure of a display device according to embodiments of the present disclosure.

FIG. 6 illustrates an example of the cross-sectional structure of a part II-II′ shown in FIG. 5.

FIG. 7 is an enlarged view of a part B of FIG. 6.

FIG. 8 is a diagram for explaining optical characteristics of a display device according to embodiments of the present disclosure.

FIG. 9 illustrates an example of a light emitting device structure of a display device according to an embodiment of the present disclosure.

### DETAILED DESCRIPTION

The advantages and features of the present disclosure and methods of the realization thereof will be apparent with reference to the accompanying drawings and detailed descriptions of embodiments. The present disclosure should not be construed as being limited to the embodiments set forth hereinafter and may be embodied in a variety of different forms. Rather, these embodiments are provided so that the present disclosure will be thorough and complete, and will fully convey the scope of the present disclosure to those having ordinary knowledge in the technical field.

The shapes, sizes, dimensions (e.g., length, width, height, thickness, radius, diameter, area, etc.), ratios, angles, numbers, and the like, inscribed in the drawings to illustrate embodiments are illustrative only, and the present disclosure is not limited to the embodiments illustrated in the drawings.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout this document, the same reference numerals and symbols will be used to designate the same or like components. In the following description of the present disclosure, detailed descriptions of known functions and components incorporated into the present disclosure will be omitted when it is determined that the description may make the subject matter in some embodiments of the present disclosure rather unclear. It will be understood that the terms “comprise”, “include”, “have”, and any variations thereof used herein are intended to cover non-exclusive inclusions unless explicitly stated to the contrary. Descriptions of components in the singular form used herein are intended to include descriptions of components in the plural form, unless explicitly stated to the contrary.

In the analysis of a component, it shall be understood that an error range is included therein, even in the situation in which there is no explicit description thereof.

When spatially relative terms, such as “on”, “above”, “under”, “below”, and “on a side of”, are used herein for descriptions of relationships between one element or component and another element or component, one or more intervening elements or components may be present between the one and other elements or components, unless a term, such as “immediately” or “directly”, is used.

In addition, terms, such as “first” and “second” may be used herein to describe a variety of components. It should be understood, however, that these components are not limited by these terms. These terms are merely used to discriminate one element or component from other elements or components. Thus, a first component referred to as first hereinafter may be a second component within the spirit of the present disclosure.

The features of example embodiments of the present disclosure may be partially or entirely coupled or combined with each other and may work in concert with each other or may operate in a variety of technical methods. In addition, respective example embodiments may be carried out independently or may be associated with and carried out in concert with other embodiments.

Hereinafter, a variety of embodiments will be described in detail with reference to the accompanying drawings.

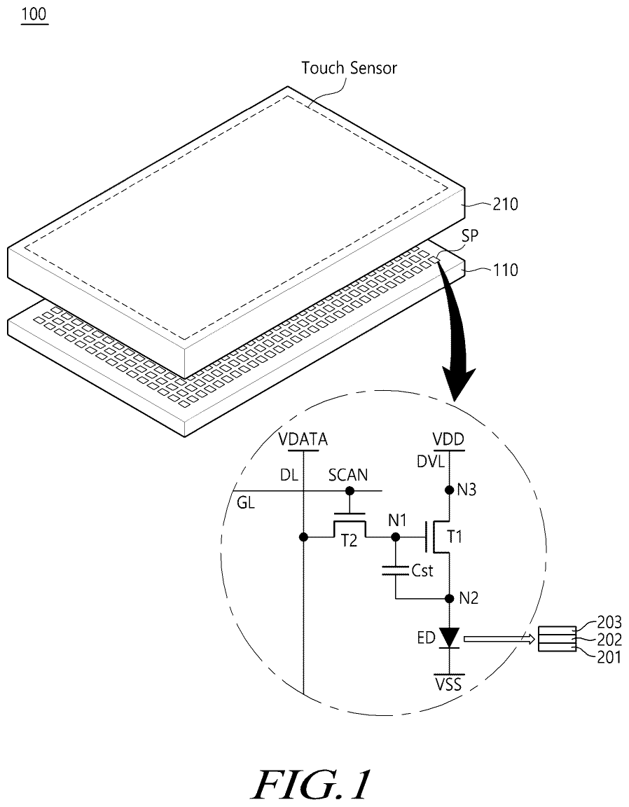

FIG. 1 illustrates an example of the structure of a display device and a circuit structure included in a subpixel according to embodiments of the present disclosure.

Referring to FIG. 1, a plurality of subpixels SP may be disposed in a display area of a display panel 110 included in a display device 100.

Each of the plurality of subpixels SP may include a light emitting element ED and a subpixel circuit unit configured to drive the light emitting element ED.

The subpixel circuit unit may include a driving transistor T1 for driving the light emitting element ED, a scan transistor T2 for transferring the data voltage VDATA to a first node N1 of the driving transistor T1, and a storage capacitor 180 for maintaining a constant voltage during one frame.

The driving transistor T1 may include a first node N1 to which a data voltage is applied, a second node N2 electrically connected to the light emitting element ED, and a third node N3 to which the driving voltage VDD is applied from a driving voltage line DVL. In the driving transistor T1, the first node N1 may be a gate node, the second node N2 may be a source node or a drain node, and the third node N3 may be a drain node or a source node. Hereinafter, for convenience of explanation, there illustrates a case in which the first node N1 is a gate node, the second node N2 is a source node, and the third node N3 is a drain node in the driving transistor T1, as an example.

The light emitting element ED may include a first electrode 201, a light emitting layer 202, and a second electrode 203. The first electrode 201 may be a pixel electrode disposed in each subpixel SP and may be electrically connected to the second node N2 of the driving transistor TI of each subpixel SP. The second electrode 203 may be a common electrode commonly disposed in the plurality of subpixels SP, and a base voltage (VSS) may be applied thereto.

Alternatively, the first electrode 201 may be a common electrode, and the second electrode 203 may be a pixel electrode. Hereinafter, for convenience of explanation, it is assumed that the first electrode 201 is a pixel electrode and the second electrode 203 is a common electrode.

The light emitting element ED may have a specific light emitting area, and the number of light emitting areas may be one or more, as will be described later.

The light emitting element ED may be an organic light emitting diode (OLED), an inorganic light emitting diode, or a quantum dot light emitting device. In the case that the light emitting element ED is an organic light emitting diode, the light emitting layer 202 in the light emitting element ED may include an organic light emitting layer containing an organic material. For example, the light emitting layer 202 may have a tandem structure having two or more stacked units, but embodiments of the present disclosure are not limited thereto.

The scan transistor T2 may be controlled on-off by a scan signal SCAN, which is a gate signal applied through a gate line GL, and the scan transistor T2 may be electrically connected between the first node N1 of the driving transistor T11 and the data line DL.

The storage capacitor Cst may be electrically connected between the first node N1 and the second node N2 of the driving transistor T1.

The subpixel circuit unit may have a 2TIC structure including two transistors DT and ST and one capacitor Cst, and in some cases, may further include one or more transistors. Alternatively, the subpixel circuit unit may further include one or more capacitors.

The storage capacitor Cst may be an external capacitor intentionally designed outside the driving transistor T1 rather than a parasitic capacitor (e.g., Cgs, Cgd) which is an internal capacitor existing between the first node N1 and the second node (N2) of the driving transistor T1. Each of the driving transistor T1 and the scan transistor T2 may be an n-type transistor or a p-type transistor.

Circuit elements within each subpixel, in particular, light emitting devices EDs implemented with organic light-emitting diodes OLEDs containing organic materials may be vulnerable to external moisture or oxygen. Accordingly, an encapsulation layer 210 may be disposed on the display panel 110 to prevent oxygen from penetrating into the circuit elements (particularly, the light emitting devices ED). The encapsulation layer 210 may be disposed to cover the light emitting element ED.

There may be additionally disposed layers providing a touch function and separate layers providing a viewing angle adjustment function on the encapsulation layer 210.

The layers providing a touch function may include layers such as a touch buffer layer, a touch interlayer insulating layer, and a touch electrode. The layers providing a viewing angle adjustment function may include a lens, a viewing angle blocking layer, etc. The layers for the touch function and the layers for the viewing angle adjustment function will be described in detail below.

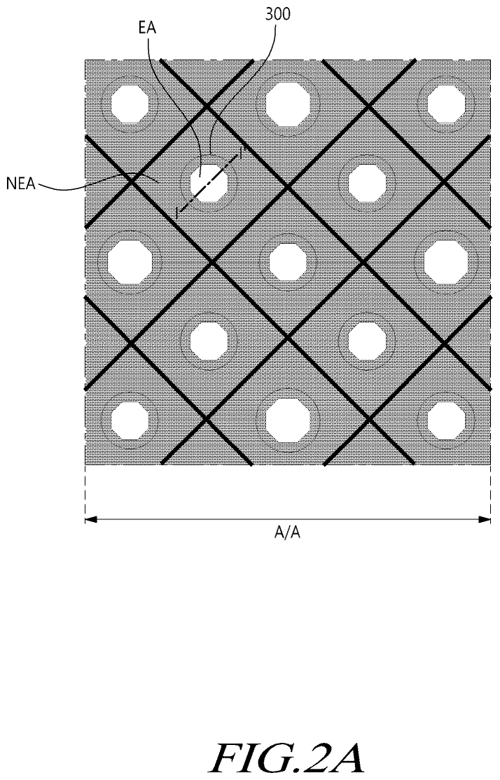

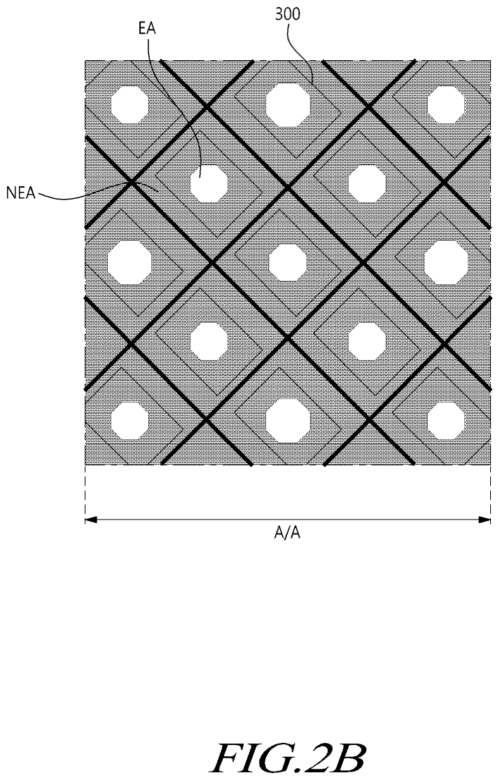

FIGS. 2A and 2B are diagrams illustrating an example of a planar structure of a display device according to embodiments of the present disclosure.

Referring to FIGS. 2A and 2B, a plurality of subpixels SP may be disposed in an active area (A/A) of a display device 100.

Each of the plurality of subpixels SP may include at least one light emitting area EA.

The light emitting area EA may be defined as an area where a first electrode 201, a light emitting layer 202 and a second electrode 203 are sequentially stacked. For example, the first electrode 201 may be an anode electrode. For example, the second electrode 203 may be a cathode electrode.

Each light emitting area EA of the subpixel SP may be surrounded by a non-emission area NEA. That is, an area excluding the light emitting area EA may be a non-emission area NEA. Additionally, the non-emission area NEA of one subpixel SP may be connected to the non-emission area NEA of another subpixel SP.

A blocking layer 221 or a metal layer 223 may be disposed on the non-emission area NEA, as will be described later. The metal layer 223 may include a touch electrode. In some examples, the metal layer 223 is formed of the same material as a touch electrode.

A lens 300 may be disposed on an area which overlaps with the light emitting area EA.

The lens 300 may be arranged to cover the light emitting area EA of each subpixel SP on a plane view. A horizontal width of the lens 300 may be greater than a width of the light emitting area EA. However, the present disclosure is not limited thereto, and at least a portion of the horizontal width of the lens 300 may be equal to the width of the light emitting area EA.

As shown in FIGS. 2A and 2B, the lens 300 may be arranged to correspond to one subpixel SP and cover the light emitting area EA included in one subpixel SP. However, it is not necessarily limited thereto, and the lens 300 may be arranged to correspond to the plurality of subpixels SP and cover all of the respective light emitting areas EA included in the plurality of subpixels SP.

The lens 300 may function to change the path of light coming from the light emitting area EA.

Depending on its three-dimensional shape, the lens 300 may function to change the path of light in all directions among the light coming from the light emitting area EA, or it may function to change only the path of light in a specific direction.

In the case that the lens 300 serves to change the path of light in all directions among the light coming from the light emitting area EA, the lens 300 may have a shape shown in FIG. 2A.

Referring to FIG. 2A, the lens 300 may have a circular cross-sectional area on a plane, or may have a half sphere shape with a convex upper surface in a direction perpendicular to the plane shown in FIG. 2A.

If the lens 300 has a hemispherical shape or the half sphere shape which is convex upward in an area overlapping with the light emitting area EA, that is, if the vertical height of the lens 300 increases toward a center of the light emitting area EA, the light emitted from the light emitting area EA may be refracted on an upper surface of the lens 300 and bent toward the center of the light emitting area EA.

That is, the lens 300 shown in FIG. 2A may serve to collect light in all directions coming from the light emitting area EA into a narrow range within a viewing angle.

If the lens 300 serves to change the path of light in a specific direction among the light coming from the light emitting area EA, the lens 300 may have the shape shown in FIG. 2B.

Referring to FIG. 2B, the lens 300 may have a rectangular cross-sectional area on a plane view and a half cylinder shape or a semi-cylindrical shape with a partially convex upper surface in a direction perpendicular to the plane shown in FIG. 2B. That is, when the lens 300 is cut in a direction perpendicular to the plane shown in FIG. 2B, the cross section may be a semicircle with a constant area.

If the lens 300 has a half cylinder shape in the area overlapping the light emitting area EA, light in a specific direction coming from the light emitting area EA may be refracted on the upper surface of the lens 300 and directed to the center of the light emitting area EA. For example, among the light coming from the light emitting area EA, light traveling in a direction parallel to the top or bottom surface of the half cylinder may be refracted at the upper surface of the lens 300 and directed to the center of the light emitting area EA.

That is, the lens 300 shown in FIG. 2B may serve to collect light in a specific direction among the light emitted from the light emitting area EA into a narrow range within a viewing angle. However, among the light coming from the emission area EA, light in directions other than the specific direction for collecting the light may be not collected in a narrow range within the viewing angle.

As described above, the direction or degree of viewing angle limitation may vary depending on the shape of the lens 300. Therefore, there may be implemented a switchable privacy mode by varying the shape of the lens 300 for each area where the subpixel SP is placed.

For example, in areas where there is little need for privacy protection, there may be used a half-cylindrical lens as shown in FIG. 2B in each subpixel SP to limit the viewing angle only in the up and down directions and not to limit the viewing angle in the left and right directions, thereby securing a wide viewing angle.

On the other hand, in areas where the need for privacy protection is high, there may be placed a hemispherical lens or a half-spherical lens as shown in FIG. 2A in each subpixel SP to limit the viewing angles in all directions, up, down, left, and right, thereby selectively securing the narrow viewing angle.

That is, although not shown in detail in FIG. 2A or FIG. 2B, a display device 100 may selectively implement a wide viewing angle or a narrow viewing angle by differentiating an area with the half-cylindrical lens from an area with the half-spherical lens and driving each subpixel SP at different timings.

Meanwhile, among the light emitted from the light emitting element ED, the light which does not reach the lens 300 may be absorbed by a blocking layer 221 to be described later or reflected by a metal layer 223 to be described later. That is, there may be effectively implemented the above-described viewing angle limitation technology by allowing light which cannot be directed to the lens 300 to be absorbed inside the display device 100

Hereinafter, it will be described the cross-sectional structure of the display device 100 including the lens 300, the blocking layer 221, and the metal layer 223.

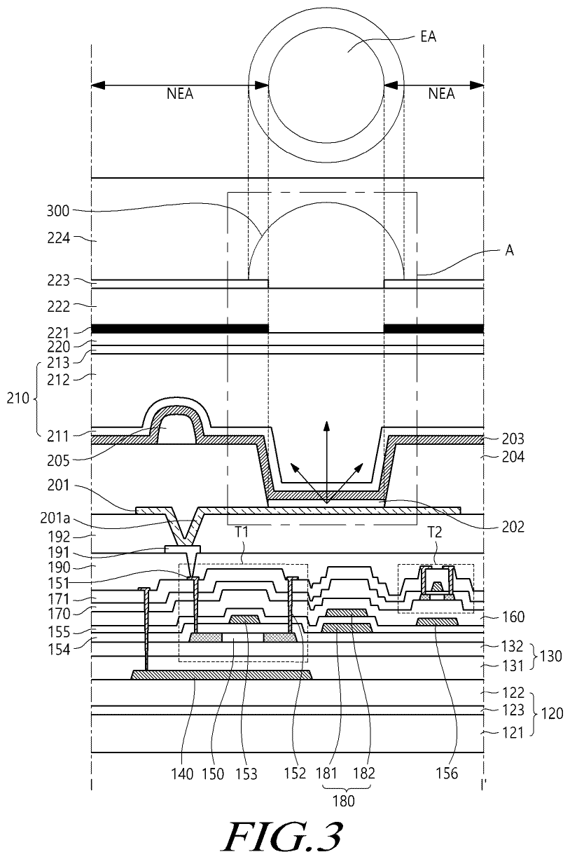

FIG. 3 illustrates an example of the cross-sectional structure of a part I-I′ shown in FIG. 2.

Referring to FIG. 3, the display device 100 may include a substrate 120.

The substrate 120 may include a first substrate 121 and a second substrate 122, and may include an intermediate film 123 between the first substrate 121 and the second substrate 122. Here, for example, the intermediate film 123 may be an inorganic film and may serve to block moisture penetration.

A first buffer layer 130 may be disposed on the substrate 120.

The first buffer layer 130 may be a single layer or multiple layers. If the first buffer layer 130 is a multiple layers, the first buffer layer 130 may include a multi-buffer layer 131 and an active buffer layer 132.

A first light blocking layer 140 may be disposed between the first buffer layer 130 and the substrate 120. The first light blocking layer 140 may overlap all or part of a first active layer

The first light blocking layer 140 may function as a light shield for blocking light coming from the bottom.

There may be formed various transistors T1 and T2, a storage capacitor 180, and various electrodes or signal lines on the first buffer layer 130.

A first transistor T1 may be disposed on the first buffer layer 130. The first transistor T1 may include a first active layer 150, a first source electrode 151, a first drain electrode 152, and a first gate electrode 153.

A first gate insulating layer 154 may be disposed on the first active layer 150 of the first transistor T1.

Here, the first active layer 150 of the first transistor T1 may include a first channel region overlapping the first gate electrode 153, a first source connection region located on one side of the first channel region, and a first drain connection region located on the other side of the first channel region.

A first interlayer insulating layer 155 may be disposed on the first gate insulating layer 154.

A second buffer layer 160 and a second gate insulating layer 170 may be disposed on the first interlayer insulating layer 155. A second light blocking layer 156 may be disposed between the first interlayer insulating layer 155 and the second buffer layer 160. The second light blocking layer 156 may have the same function as the first light blocking layer 140.

A second transistor T2 may be disposed on the second buffer layer 160. The second transistor T2 may be a transistor for transmitting various signals or voltages to various electrodes inside a display panel.

A second interlayer insulating layer 171 may be disposed on the second transistor T2.

The first source electrode 151 and the first drain electrode 152 of the first transistor T1 may be disposed on the second interlayer insulating layer 171.

The first source electrode 151 and the first drain electrode 152 of the first transistor T1 may be connected to the first source connection region and the first drain connection region of the first active layer 150, respectively, via the through holes of the second interlayer insulating layer 171, the second gate insulating layer 170, the second buffer layer 160, the first interlayer insulating layer 155, and the first gate insulating layer 154.

A storage capacitor 180 may include a first capacitor electrode 181 and a second capacitor electrode 182. The first interlayer insulating layer 155 may be disposed between the first capacitor electrode 181 and the second capacitor electrode 182.

A third interlayer insulating layer 190 may be disposed on the first transistor T1. That is, the third interlayer insulating layer 190 may be disposed on the first source electrode 151 and the first drain electrode 152 of the first transistor T1.

A connection electrode 191 may be disposed on the third interlayer insulating layer 190.

The connection electrode 191 may be an electrode capable of relaying the electrical connection between the first source electrode 151 of the first transistor T1 and the first electrode 201 of the light emitting element ED.

The connection electrode 191 may be electrically connected to the first source electrode 151 of the first transistor T1 through a hole in the third interlayer insulating layer 190.

A first planarization layer 192 may be disposed on the connection electrode 191 and the third interlayer insulating layer 190.

Although FIG. 3 illustrates a structure in which the first planarization layer 192 is disposed on the third interlayer insulating layer 190, embodiments of the present disclosure are not limited thereto. For example, the first planarization layer 192 may be disposed on the third interlayer insulating layer 190 and another planarization layer may be additionally disposed on the first planarization layer 192.

The first electrode 201 of the light emitting element ED may be disposed on the first planarization layer 192.

The first electrode 201 may be made of an opaque conductive material for reflecting the light. For example, opaque conductive materials may include at least one of a metal such as aluminum (Al), gold (Au), silver (Ag), copper (Cu), tungsten (W), molybdenum (Mo), chromium (Cr), tantalum (Ta) and titanium (Ti) or alloys thereof, but is not limited thereto.

FIG. 3 illustrates the first electrode 201 having a single-layer structure, but it is not necessarily limited thereto.

A bank layer 204 may be disposed on the first electrode 201 and the first planarization layer 192.

The bank layer 204 may include a bank hole exposing a portion of the upper surface of the first electrode 201. That is, the bank hole formed in the bank layer 204 may overlap with a portion of the first electrode 201.

A light emitting layer 202 may be disposed on the bank hole exposing a portion of the upper surface of the first electrode 201. That is, the light emitting layer 202 may be disposed on the first electrode 201 that does not overlap the bank layer 204.

A second electrode 203 may be disposed on the light emitting layer 202 and the bank layer 204.

The second electrode 203 may be made of a transparent conductive material.

At least one spacer 205 may exist between the second electrode 203 and the bank layer 204. At least one spacer 205 may be arranged to overlap a contact hole area. The contact hole area formed in the first planarization layer 192 and the second planarization layer 193 may be filled with the bank layer 204 and a spacer 205 is formed on the upper part of the contact hole area, so that a height of the bank layer 204 in the contact hole area including the spacer 205 may be greater than a height of the bank layer 204 partially overlapping an opening area.

The spacer 205 may be formed of the same material as the bank layer 204, but is not limited thereto. The bank layer 204 and spacer 205 may be formed of a transparent insulating material.

An encapsulation layer 210 may be disposed on the second electrode 203.

The encapsulation layer 210 may include a first encapsulation layer 211, a second encapsulation layer 212 on the first encapsulation layer 211, and a third encapsulation layer 213 on the second encapsulation layer 212.

The first encapsulation layer 211 and the third encapsulation layer 213 may be made of at least one inorganic material selected from silicon nitride (SiNx), silicon oxide (SiOx), or aluminum oxide (AlyOz), but are limited thereto. The first encapsulation layer 211 and the third encapsulation layer 213 may be formed using a vacuum deposition method such as a chemical vapor deposition (CVD) or an atomic layer deposition (ALD), but is not limited thereto.

The second encapsulation layer 212 may cover foreign substances or particles that may occur during the manufacturing process. Additionally, the second encapsulation layer 212 may planarize the surface of the first encapsulation layer 211.

There may be disposed the layers for providing a touch function on the encapsulation layer 210.

The layer for providing the touch function may include a touch buffer layer 220, a touch interlayer insulating layer 222, a metal layer 223, and a touch planarization layer 224. As described above, the metal layer 223 may include a touch electrode.

Specifically, the touch buffer layer 220 may be disposed on the third encapsulation layer 213. The touch buffer layer 220 may block external moisture from penetrating into the light emitting element ED containing organic materials.

A blocking layer 221 and a touch interlayer insulating layer 222 may be disposed on the touch buffer layer 220.

The blocking layer 221 may be made of at least one of black pigment, black resin, graphite, black ink, gravure ink, black spray, and black enamel. If the blocking layer 221 is made of the above materials, the blocking layer may absorb at least 80% of visible light.

The blocking layer 221 may be arranged to be spaced apart. The area where the blocking layers 221 are spaced apart may correspond to the light emitting area EA. That is, a separation distance between the blocking layers 221 may be equal to the width of the light emitting area EA, but is not limited thereto, and may be greater than the width of the light emitting area EA.

The blocking layer 221 may not overlap the light emitting area EA. That is, the blocking layer 221 may be disposed on the non-emission area NEA. The blocking layer 221 may be arranged to cover all of the non-emission area NEA on a plane view, or may be arranged to cover a portion of the non-emission area NEA.

Alternatively, the blocking layer 221 may have an area that partially overlaps the light emitting area EA. In this case, the blocking layer 221 may be arranged to cover all of the non-emission area NEA, and may cover a portion of the light emitting area EA. In addition, a width of the area where the blocking layer 221 is opened may be smaller than a width of the light emitting area EA.

The metal layer 223 may be disposed on the touch interlayer insulating layer 222. The metal layers 223 may be arranged to be spaced apart. For example, the metal layer 223 may be on the same layer and made of the same material as the touch electrode.

The separation distance between the metal layers 223 may be the same as the separation distance between the blocking layers 221. That is, the separation distance between the metal layers 223 may be equal to or smaller than the width of the light emitting area EA.

The metal layer 223 may not overlap the light emitting area EA. That is, as the blocking layer 221, the metal layer 223 may be disposed on the non-emission area NEA. The metal layer 223 may be disposed in an area including the entire non-emission area NEA on a plane view, or may be disposed only on a portion of the non-emission area NEA.

Alternatively, the metal layer 223 may have an area that partially overlaps the light emitting area EA. In this case, the metal layer 223 may be disposed in an area including all of the non-emission area NEA. Additionally, the separation distance between the metal layers 223 may be smaller than the width of the light emitting area EA.

The metal layer 223 may transmit a touch detection signal to a touch driving circuit (not shown) or receive a touch driving signal from the touch driving circuit.

A lens 300 and the touch planarization layer 224 may be disposed on the metal layer 223.

As described above, the lens 300 may have a convex upper surface in a direction perpendicular to the substrate 120.

The lens 300 may be disposed in an area that overlaps the light emitting area EA. The maximum horizontal width of the lens 300 may be greater than the light emitting area EA. However, it is not limited thereto, and the maximum horizontal width of the lens 300 may be equal to the width of the light emitting area EA.

However, it is preferable that the maximum horizontal width of the lens 300 is not smaller than the width of the light emitting area EA. In the case that the maximum horizontal width of the lens 300 is smaller than the width of the light emitting area EA, the lens 300 and the metal layer 223 may be spaced apart. A touch planarization layer 224 may be disposed in an area where the lens 300 and the metal layer 223 are spaced apart.

In this case, a part of the light emitted from the light emitting layer 202 may travel to a separation space between the lens 300 and the metal layer 223, that is, the area where the touch planarization layer 224 is disposed. Light traveling to the area where the touch planarization layer 224 is disposed may not pass through the interface between the touch interlayer insulating layer 222 and the touch planarization layer 224 and may be totally reflected at the interface.

For example, if the maximum width in the horizontal direction of the lens 300 is smaller than the width of the light emitting area EA, some of the emitted light does not enter the inside of the lens 300, and this light may be totally reflected inside the display device 100 and may be not emitted outside of the display device 100. Accordingly, the maximum horizontal width of the lens 300 may be greater than or equal to the width of the light emitting area EA.

The touch planarization layer 224 may be disposed to cover the metal layer 223 and the lens 300, and may be formed of the same material as the second encapsulation layer 212, but is not limited thereto.

Hereinafter, it will be described a cross-sectional structure of the display device 100 including the lens 300, the blocking layer 221, and the metal layer 223 in detail.

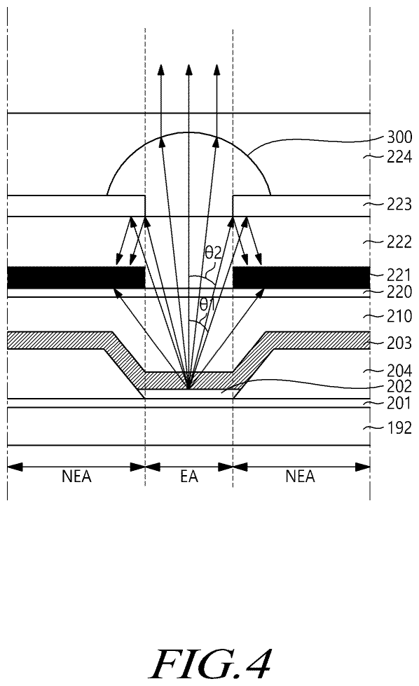

FIG. 4 is an enlarged view of part A of FIG. 3.

Referring to FIG. 4, light emitted from the light emitting area EA of the subpixel SP may travel toward the top of a display device 100 in the case of a display device 100 of a top emission type.

A part of the light traveling toward the top of the display device 100 may be absorbed or reflected inside the display device 100, and may be trapped inside the display device 100 instead of traveling outside. Alternatively, a part of the light may be refracted and directed to a specific direction. Accordingly, the user of the display device 100 may recognize only a portion of the light emitted from the display device 100.

Specifically, if an angle θ between the light emitted from the light emitting layer 202 and a vertical direction perpendicular to the substrate 120 is greater than θ1, the light emitted from the light emitting layer may travel toward the blocking layer 221, so that most of it may be absorbed into the blocking layer 221. That is, among the light emitted from the light emitting layer, light with an angle θ formed with the vertical direction of the substrate 120 of θ1 or more may not be emitted to the outside of the display device 100.

If an angle θ between the light emitted from the light emitting layer 202 and the vertical direction of the substrate 120 is greater than θ2 and less than θ1, the light emitted from the light emitting layer may be reflected on the metal layer 223. The light reflected by the metal layer 223 may travel toward the blocking layer 221 again and may be absorbed by the blocking layer 221. That is, among the light emitted from the light emitting layer, light whose angle θ with the vertical direction of the substrate 120 is greater than or equal to θ2 and less than θ1 may not be emitted to the outside of the display device 100.

If the angle θ between the light emitted from the light emitting layer and the vertical direction of the substrate 120 is less than θ2, the light emitted from the light emitting layer may travel toward the inside of the lens 300 without being absorbed by the blocking layer 221 or being absorbed again in the blocking layer 221 after being reflecting from the metal layer 223. The light traveling inside the lens 300 may be refracted at the upper surface of the lens 300 and emitted to the outside of the display device 100.

In this case, due to the difference in refractive index between the lens 300 and the touch planarization layer 224 surrounding the lens, the path of light passing through the upper surface of the lens 300 may be changed to point toward the axis of symmetry of the lens 300. Here, the axis of symmetry of the lens 300 may be a vertical axis formed at a portion of the lens with the largest vertical width.

That is, as described above, the light emitted from the light emitting layer 202 may be absorbed by the internal components of the display device 100, may be reflected back inside, or may be refracted at the interface of a specific component, thereby being changed the path of the light. Accordingly, among the light emitted from the light emitting layer 202, only light whose angle θ with the vertical direction of the substrate 120 is smaller than θ2 may be emitted to the outside of the display device 100.

Therefore, only when the user views the display device 100 from a position offset by an angle smaller than θ2 with respect to the front direction of the display device 100, the light emitted from the light emitting layer 202 may be visible.

Moreover, even when the angle θ of the light emitted from the light emitting layer 202 with the vertical direction of the substrate 120 is smaller than θ2, as described above, the path of the emitted light may be changed to be directed to the axis of symmetry of the lens 300 due to refraction on the upper surface of the lens 300. Therefore, the user of the display device 100 may recognize the light emitted from the light emitting layer 202 only when the viewing angle of the display device 100 is smaller.

Accordingly, the viewing angle of the display device 100 may be limited. That is, if the display device 100 includes the blocking layer 221, the metal layer 223 and the lens 300, the light emitted from the light emitting layer 202 may be emitted to the outside of the display device 100 only through a limited area in the viewing angle range of the display device 100. Accordingly, there may be limited an area in which the user of the display device 100 can recognize images provided through the display screen.

Therefore, the display device 100 may effectively provide a privacy protection function by including not only the lens 300 but also the blocking layer 221 and the metal layer 223.

In addition, the range of the viewing angle at which light emitted from the light emitting layer 202 can be emitted to the outside may vary by adjusting the arrangement structure and spacing of the internal components included in the display device 100, that is, the blocking layer 221, the metal layer 223 and the lens 300. Therefore, it is possible to adjust a limitation degree of the viewing angle by adjusting the structure or spacing of internal components according to the usage situation. That is, the degree of privacy protection may be adjusted depending on the situation.

Meanwhile, in the case that the display device 100 includes the blocking layer 221 and the metal layer 223 as shown in FIG. 4, some of the light emitted from the light emitting layer 202 may be absorbed by the blocking layer 221 inside the display device 100, or may be reflected from the metal layer 223 and absorbed again by the blocking layer 221. Therefore, the luminance of the display device 100 may decrease within the viewing angle range. In addition, the light extraction efficiency of the display device 100 may decrease accordingly.

For example, in the case that the blocking layer 221 and the metal layer 223 are disposed, there may provide an improved viewing angle limiting function, but at the same time, the luminance of the display device 100 may decrease and the light extraction efficiency may decrease.

Hereinafter, it will be described a solution to this problem with reference to the drawings.

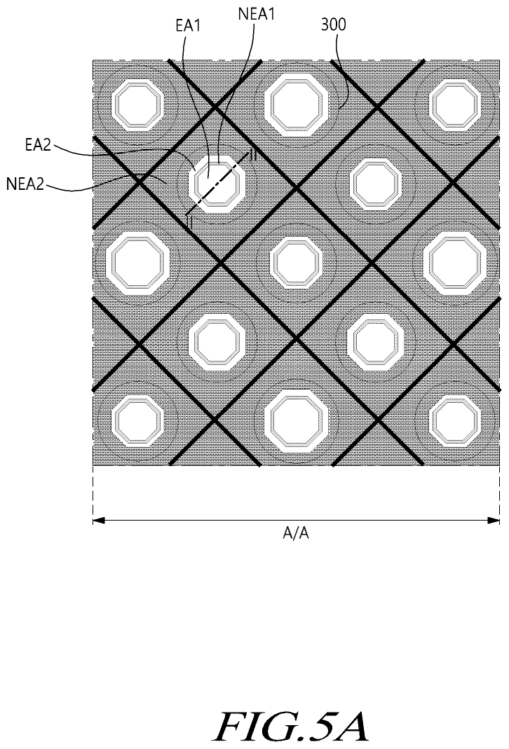

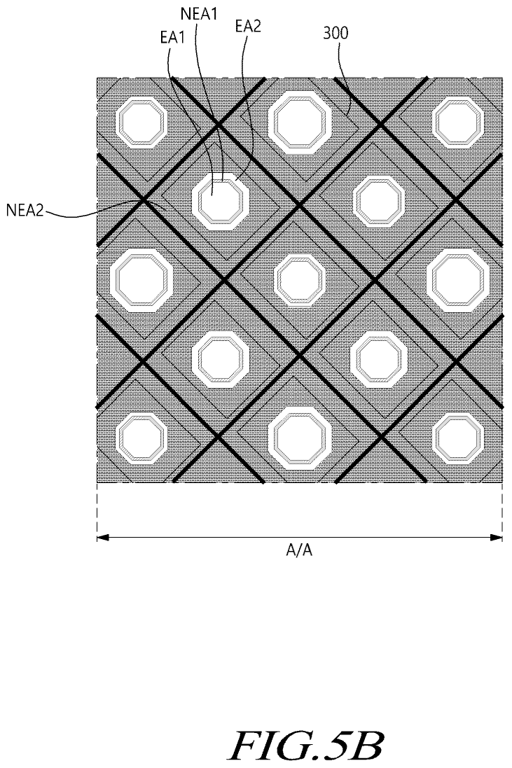

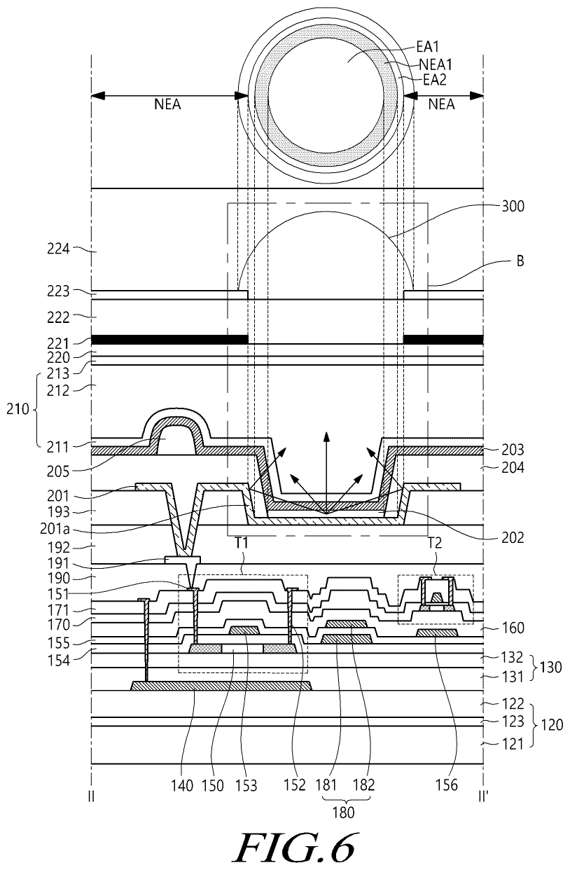

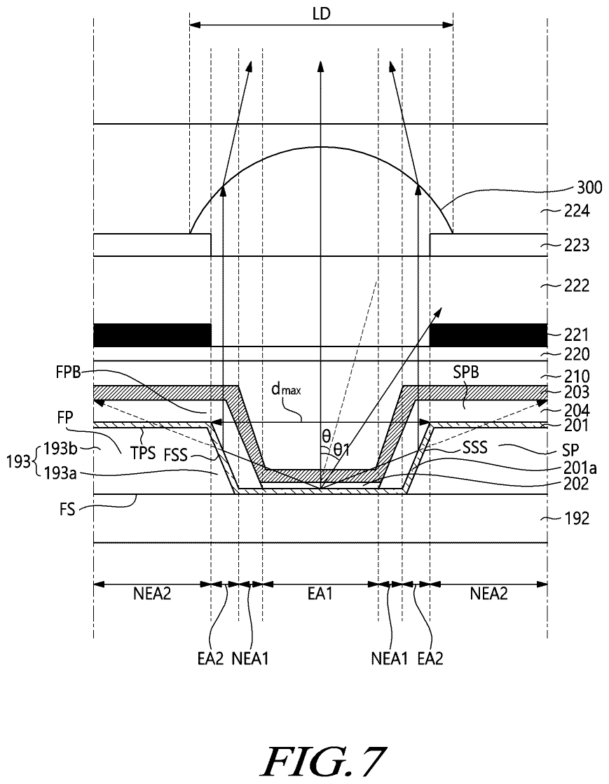

FIGS. 5A and 5B are diagrams illustrating another example of a planar structure of a display device according to embodiments of the present disclosure. FIG. 6 illustrates an example of the cross-sectional structure of a part II-II′ shown in FIG. 5. FIG. 7 is an enlarged view of a part B of FIG. 6.

The planar and cross-sectional structures of the display device 100 shown in FIGS. 5A, 5B, and FIG. 6 may be the same as the planar and cross-sectional structures of the display device 100 described with reference to FIGS. 2A, 2B, and FIG. 3 except that the display device 100 further includes a second planarization layer 193 and the structure of the first electrode 201 is changed. Therefore, there may be omitted the redundant explanation.

Referring to FIGS. 5A, 5B, and FIG. 6, each of the plurality of subpixels SP disposed in the active area A/A of the display device 100 may include a first light emitting area EA1 and the second light emitting area EA2.

The first light emitting area EA1 may be defined as an area in which a first electrode 201, a light emitting layer 202, and a second electrode 203 are sequentially stacked.

The second light emitting area EA2 may be an area formed by light which is emitted from the light emitting layer 202 and is reflected by the first electrode 201.

The first light emitting area EA1 may be surrounded by a first non-emission area NEA1. The first non-emission area NEA1 may be an area which is black when a display panel is in an ON state. Alternatively, the first non-emission area NEA1 may be an area having lower luminance than the first and second light emitting areas EA1 and EA2 due to light incident from at least one of the first and second light emitting areas EA1 and EA2.

The first non-emission area NEA1 may be surrounded by the second light emitting area EA2.

The second light emitting area EA2 may be surrounded by a second non-emission area NEA2.

A second non-emission area NEA2 of one subpixel SP may be connected to a second non-emission area NEA2 of another subpixel SP. That is, the second non-emission area NEA2 may mean an area between the second light emitting area EA2 of one subpixel SP and the second light emitting area EA2 of another subpixel SP.

Referring to FIG. 6, the display device includes a first light emitting area EA1, a first non-emission area NEA1, and a second light emitting area EA2 from a plan view. Further, the first non-emission area NEA1 is disposed between the first light emitting area EA1 and the second light emitting area EA2 from a plan view.

A lens 300 may be disposed in an area which overlaps with the first light emitting area EA1 and the second light emitting area EA2.

The lens 300 may be arranged to cover the first light emitting area EA1 and the second light emitting area EA2 of each subpixel SP on a plane view.

The lens 300 may be arranged to cover all of the first light emitting area EA1, the first non-emission area NEA1 and the second light emitting area EA2 of each subpixel SP on a plane view, as shown in FIG. 5A or FIG. 5B.

For example, the lens 300 may at least partially overlap the first light emitting area EA1, the first non-emission area NEA1 and the second light emitting area EA2 of each subpixel SP.

That is, a horizontal width of the lens 300 may be greater than the sum of the widths of the first light emitting area EA1, the first non-emission area NEA1 and the second light emitting area EA2. However, it is not limited thereto, and at least a portion of the horizontal width of the lens 300 may be equal to the sum of the widths of the first light emitting area EA1, the first non-emission area NEA1 and the second light emitting area EA2.

As shown in FIGS. 5A and 5B, the lens 300 may be arranged to correspond to one subpixel SP and cover the first light emitting area EA1 and the second light emitting area EA2 included in one subpixel SP. However, it is not necessarily limited thereto, and the lens 300 may be arranged to correspond to the plurality of subpixels SP and cover each of the first light emitting area EA1 and the second light emitting area EA2 included in the plurality of subpixels SP.

As described above, in the case that the lens 300 serves to change the path of light in all directions among the light coming from the first light emitting area EA1 and the second light emitting area EA2, the lens 300 may have the shape shown in FIG. 5A.

Referring to FIG. 5A, the lens 300 may have a half sphere shape or a half-spherical shape with a circular cross-sectional area on a plane and a convex upper surface in a direction perpendicular to the plane shown in FIG. 5A.

If the lens 300 has a half-spherical shape which is convex upward in an area

overlapping the light emitting area EA, that is, if a vertical height of the lens 300 increases toward a center of the first light emitting area EA1, the light emitted from the first light emitting area EA1 and the second light emitting area EA2 may be refracted on an upper surface of the lens 300 and directed to the center of the first light emitting area EA1.

That is, the lens 300 shown in FIG. 5A may serve to collect light in all directions coming from the first and second light emitting areas EA1 and EA2 into a narrow range within a viewing angle.

Alternatively, if the lens 300 serves to change the path of light in a specific direction among the light coming from the first light emitting area EA1 and the second light emitting area EA2, the lens 300 may have the shape as shown in FIG. 5B.

Referring to FIG. 5B, the lens 300 may have a half cylinder shape with a rectangular cross-sectional area on a plane and a partially convex upper surface in a direction perpendicular to the plane shown in FIG. 5B. Here, when the lens 300 is cut in a direction perpendicular to the plane shown in FIG. 5B, the cross section may be a semicircle with a constant area.

If the lens 300 has a half cylinder shape in the area overlapping the first light emitting area EA1 and the second light emitting area EA2, the light in a specific direction emitted from the first light emitting area EA1 and the second light emitting area EA2 may be refracted on an upper surface of the lens 300 and directed to the center of the first light emitting area EA1. For example, among the light coming from the first light emitting area EA1, the light traveling in a direction parallel to the upper or bottom surface of the half cylinder may be refracted at the upper surface of the lens 300 and bent toward the center of the first light emitting area EA1.

That is, the lens 300 shown in FIG. 5B may serve to collect light in a specific direction among the light emitted from the first light emitting area EA1 and the second light emitting area EA2 into a narrow range within the viewing angle. However, among the light emitted from the first light emitting area EA1 and the second light emitting area EA2, the light in directions other than the specific direction collecting light may be not collected in a narrow range within the viewing angle.

Meanwhile, as the lens 300 is arranged to cover not only the first light emitting area EA1 but also the second light emitting area EA2, a maximum width of the lens 300 in the horizontal direction may be equal to or greater than the sum of the widths of the first light emitting area EA1, the first non-emission area NEA1 and the second light emitting area EA2. Accordingly, the display device 100 may prevent a decrease in luminance while providing a viewing angle limiting function.

Hereinafter, it will be described a cross-sectional structure of the display device 100 including the lens 300, the blocking layer 221 and the metal layer 223.

Referring to FIGS. 6 and 7, a second planarization layer 193 may be disposed on a first planarization layer 192.

The second planarization layer 193 may include at least one opening area.

The opening area of the second planarization layer 193 may partially overlap with the first light emitting area EA1.

The second planarization layer 193 may be made of the same material as a first planarization layer 192, but is not limited thereto. In some embodiments, the second planarization layer 193 and the first planarization layer 192 are separate and distinct layers formed through a separate manufacturing process. However, in some embodiments, the second planarization layer 193 and the first planarization layer 192 may not be separate and distinct and may be formed as a single layer.

The horizontal width of an area where the second planarization layer 193 is opened, that is, the opening area, may be greater than a horizontal width of the first light emitting area EA1.

The second planarization layer 193 may include a first portion 193a and a second portion 193b surrounding the first portion 193a.

The first portion 193a may mean a portion where the second planarization layer 193 has an inclined side surface. That is, the first portion 193a may refer to a portion of the second planarization layer 193 whose vertical height is not constant.

The second portion 193b is a part excluding the first portion 193a, and may mean a portion surrounding the first portion 193a and having a constant vertical height.

An area where the second planarization layer 193 is opened, that is, the opening area may mean a space between the first portions 193a of the second planarization layer 193.

Referring to FIGS. 6 and 7, the lens 300 may overlap the first portion 193a of the second planarization layer 193. However, the present disclosure is not limited thereto, and the lens 300 may overlap the first portion 193a of the second planarization layer 193 and may also overlap with a part of the second portion 193b.

A first electrode 201 may be disposed in at least some areas on the first planarization layer 192 and the second planarization layer 193.

The first electrode 201 may be disposed within the opening area of the second planarization layer 193. Specifically, the first electrode 201 may be disposed on a bottom surface and a side surface of the opening area provided in the second planarization layer 193, and may be disposed to extend to a portion of an upper surface of the second planarization layer 193. The first electrode 201 may be in contact with the upper surface of the first planarization layer 192 in an area corresponding to the opening area of the second planarization layer 193.

In addition, the first electrode 201 may be in contact with a connection electrode 191 disposed below the first planarization layer 192 through contact holes provided in the second planarization layer 193 and the first planarization layer 192.

The first electrode 201 may include an inclined portion 201a.

The inclined portion 201a may be as a portion of the first electrode 201 disposed on an inclined side surface of the second planarization layer 193, that is, on an inclined surface of the first portion 193a of the second planarization layer 193. The inclined portion 201a may be disposed on each inclined surface of the first portion 193a on both sides of the opening area of the second planarization layer 193.

The inclined portion 201a may have an inclination of the same angle as the first portion 193a of the second planarization layer 193.

As described above, some of the light emitted from the light emitting layer 202 may be reflected from the inclined portion 201a to form the second light emitting area EA2, so an area where the inclined portion 201a is disposed may mean the second light emitting area EA2.

As described above, the horizontal width of the lens 300 may be equal to or greater than the sum of the widths of the first light emitting area EA1, the first non-emission area NEA1 and the second light emitting area EA2. Here, since the area where the inclined portion 201a is disposed may mean the second light emitting area EA2, a maximum horizontal distance dmax between the inclined portions 201a disposed on each inclined surface of the first portion 193a on both sides of the opening area of the second planarization layer 193 may be equal to the sum of the widths of the first light emitting area EA1, the first non-emitting area NEA1 and the second light emitting area EA2.

Here, the maximum horizontal distance dmax between the inclined portions 201a may mean the largest value among the horizontal distances from a random point on the inclined portion 201a on one side to a random point on the inclined portion 201a disposed on the other side.

Meanwhile, since the display device 100 further includes the inclined portion 201a, the display device 100 may prevent a decrease of luminance while providing a function to limit the viewing angle and increase light extraction efficiency. Hereinafter, this will be described with reference to the drawings.

Referring to FIG. 7, a blocking layer 221 and a metal layer 223 may be located outside the outer boundary of the second light emitting area EA2.

The separation distance between the blocking layers 221 may be equal to or greater than the sum of the widths of the first light emitting area EA1, the first non-emission area NEA1 and the second light emitting area EA2.

The separation distance between the metal layers 223 may be greater than the sum of the widths of the first light emitting area EA1, the first non-emission area NEA1 and the second light emitting area EA2.

As described above, among the light emitted from the light emitting layer 202, the light traveling outside the outer boundary of the second light emitting area EA2, that is, the light whose angle θ with the vertical direction of the substrate 120 is more than a specific value may be absorbed by the blocking layer 221 as described above, or may be reflected from the metal layer 223 and absorbed again into the blocking layer 221. Therefore, this light cannot be emitted outside of the display device 100.

However, if the display device 100 includes the inclined portion 201a, a part of the light emitted from the light emitting layer 202 and traveling toward the blocking layer 221 may change their path.

For example, if the display device 100 does not include the inclined portion 201a, among the light emitted from the light emitting layer 202, some of the light whose angle θ with the vertical direction of the substrate 120 is θ1 or more may travel toward the blocking layer 221. The light directed to the blocking layer 221 may be absorbed by the blocking layer 221, and therefore may not be emitted to the outside.

Referring to FIG. 7 according to an embodiment of the present disclosure, if the display device 100 includes an inclined portion 201a, some of the light whose angle θ with the vertical direction of the substrate 120 is θ1 or more may be reflected from the inclined portion 201a while traveling toward the blocking layer 221, so that it is no longer absorbed by the blocking layer 221 and can be emitted to the outside of the display device 100.

That is, if the display device 100 includes the inclined portion 201a, a greater amount of light may be emitted to the outside of the display device 100 compared to a case without the inclined portion 201a.

In addition, referring to FIGS. 6 and 7, the lens 300 may overlap the inclined portion 201a or the first portion 193a of the second planarization layer 193.

If the lens 300 is disposed to overlap the inclined portion 201a or the first portion 193a of the second planarization layer 193, some of the light emitted from the second light emitting area EA2 may proceed inside the lens 300, as shown in FIG. 7, and may be refracted at an upper surface of the lens 300 and bent toward the center of the lens 300. The lens 300 has a width LD. As will be discussed further below, the lens 300 has width LD such that it overlaps with a top surface TPS and a side surface FSS of the second planarization layer 193 from a plan view.

That is, not only the light emitted from the first light emitting area EA1 but also the light emitted from the second light emitting area EA2 may travel toward the inside of the lens 300.

In summary, the display device 100 including the inclined portion 201a, lens 300, blocking layer 221 and metal layer 223 may absorb or refract a part of the light emitted from the light emitting layer 202 so as to provide a viewing angle limitation function. In addition, in the case that the display device 100 includes the inclined portion 201a, more light can be emitted to the outside, thereby preventing a decrease in luminance within the viewing angle while providing a viewing angle limiting function.

In addition, if the display device 100 includes the inclined portion 201a, the light emitted through the second light emitting area EA2 in addition to the light emitted from the first light emitting area EA1 may be emitted to the outside of the display device 100. Therefore, the light extraction efficiency of the display device 100 may be increased.

Referring to FIG. 7, the first planarization layer 192 has a first surface FS. The second planarization layer 193 is on the first planarization layer 192. As shown, the second planarization layer 193 has a first portion FP (e.g., a portion as shown on the left side of FIG. 7) and a second portion SP (e.g., a portion as shown on the right side of FIG. 7) opposite and facing the first portion FP. The first portion FP and the second portion SP are spaced apart from each other.

The bank layer 204 is on the first portion FP and the second portion SP of the second planarization layer 193. That is, the bank layer 204 also has a first portion FPB and a second portion SPB that is respectively on the first portion FP and the second portion SP of the second planarization layer 193. The first portion FPB of the bank layer 204 extends over and covers a top surface TPS of the first portion FP of the second planarization layer 193 and a side surface FSS (may also be referred to as a first side surface) of the first portion FP of the second planarization layer 193.

As shown in FIG. 7, the lens 300 overlaps the at least one of the first portion FP or the second portion SP of the second planarization layer 193 from a plan view.

In some embodiments, the first electrode 201 is on and contacts the first surface FS of the first planarization layer 192. As shown, the first electrode 201 extends from top surface TPS of the first portion FP of the second planarization layer 193 and the side surface FSS of the first portion FP of the second planarization layer 193 and contacts the first surface FS of the first planarization layer 192.

As described previously, the first portion FP of the second planarization layer 193 includes a first side surface FSS and the second portion SP of the second planarization layer 193 includes a second side surface SSS opposite and facing the first side surface FSS. In some embodiments, the first electrode 201 is on and contacts the first side surface FSS of the second planarization layer 193, the first surface FS of the first planarization layer 192, and the second side surface SSS of the second planarization layer 193.

Similarly, the second portion SPB of the bank layer 204 extends over and covers a top surface of the second portion SP of the second planarization layer 193 and a second side surface SSS of the second portion SP of the second planarization layer 193.

Here, the light emitting layer 202 is disposed between the first portion FP of the second planarization layer 193 and the second portion SP of the second planarization layer 193 and the light emitting layer 202 is spaced apart from both the first portion FP and the second portion SP of the second planarization layer 193.

In some embodiments, the first light emitting area EA1 overlaps with the light emitting layer 202 from a plan view. In some embodiments, the second light emitting area EA2 overlaps with the at least one of the first side surface FSS of the first portion FP of the second planarization layer 193 and the second side surface SSS of the second portion SP of the second planarization layer 193 from a plan view.

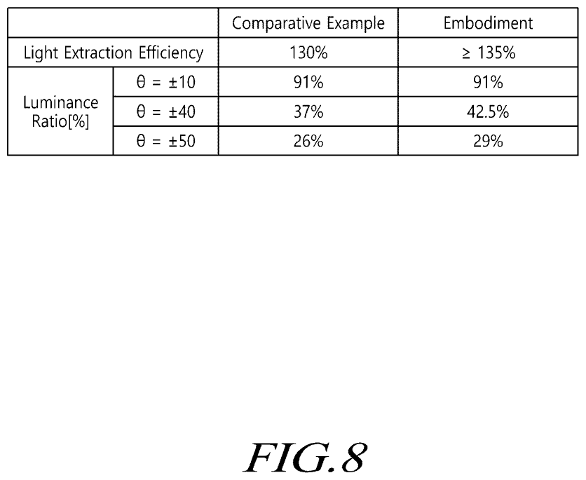

FIG. 8 is a diagram for explaining optical characteristics of a display device according to embodiments of the present disclosure.

FIG. 8 illustrates that a display device 100 (embodiment) having a second light emitting area EA2 by a second planarization layer 193 and a display device 100 (comparative example) without a second light emitting area EA2 by a second planarization layer 193 have different light extraction efficiency and luminance within the viewing angle.

In the case of light extraction efficiency, a display device 100 having the second light emitting area EA2 has a value of 135% or more (≥135%), which is higher than 130% of a display device 100 without the second light emitting area EA2.

In relation to the luminance ratio, an angle value θ in the table of FIG. 8 may mean the angle θ formed by the light coming from the light emitting layer 202 and the vertical direction of the substrate 120.

The angle θ formed by the light emitted from the light emitting layer 202 and the vertical direction of the substrate 120 may refer to an angle formed based on a front direction of the display device. That is, the angle may mean a degree to which a display screen viewing direction of an user is deviated from the front of the display screen. For example, in the case that a user views the display screen from the front, the angle θ between the light coming from the light emitting layer and the vertical direction of the substrate 120 may be θ degrees. Alternatively, if a user views the display screen from the side of the display screen, the angle θ formed by the light coming from the light emitting layer and the vertical direction of the substrate 120 may be 90 degrees.

The luminance ratio may refer to the ratio of luminance at an angle offset by a specific angle from the front of the display screen, that is, a specific angle θ formed by the light coming from the light emitting layer 202 and the vertical direction of the substrate 120 with respect to the luminance at the front of the display screen.

In the area where the angle θ between the light coming from the light emitting layer 202 and the vertical direction of the substrate 120 is +40, the luminance ratio of the display device is 42.5%, which represents an increase in luminance compared to 37% in the comparative example.

In the area where the angle θ between the light coming from the light emitting layer 202 and the vertical direction of the substrate 120 is +50, the luminance ratio of the display device is 29%, which represents an increase in luminance compared to 26% in the comparative example.

That is, if the display device 100 includes the second light emitting area EA2, the light extraction efficiency of the display device 100 may increase and the luminance of the display device 100 may increase in a specific area within the viewing angle.

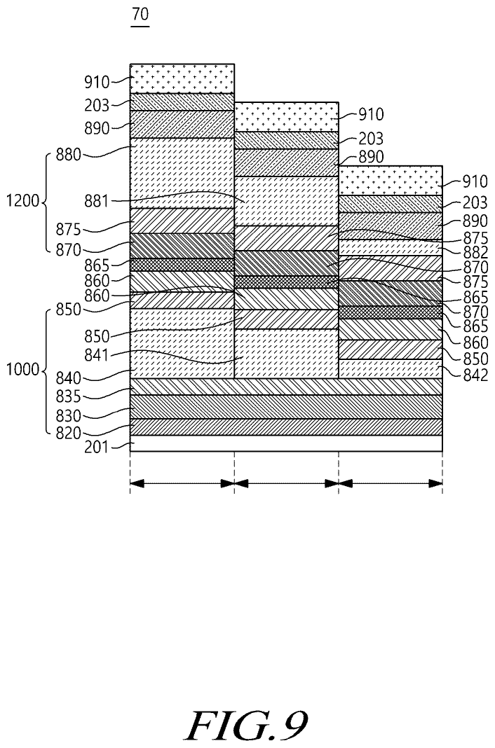

FIG. 9 illustrates an example of a light emitting device structure of a display device according to an embodiment of the present disclosure.

Referring to FIG. 9, the display device may include a light emitting element ED.

The light emitting element ED may be include a first electrode 201 formed on a substrate in which a red subpixel region Rp, a green subpixel region Gp and a blue subpixel region Bp are defined, a first organic emission layer consisting of a hole injection layer (820; HIL), a first hole transport layer (830; 1st HTL), a first hole control layer (835; 1st HCL), a first red emission layer (840; 1st Red EML), a first green emission layer (841; 1st Green EML) and a first blue emission layer (842; 1st Blue EML), a second organic emission layer consisting of a first electron transport layer (850; 1st ETL), a first charge generation layer (860; N-CGL), a second charge generation layer (865; P-CGL), a second hole transport layer (870; 2nd HTL), a second hole control layer (875; 2nd HCL), a second red emission layer (880, Red EML), a second green emission layer (881; 2nd Green EML) and a second blue emission layer (882; 2nd Blue EML), a second electron transporting layer (890, 2nd ETL), a second electrode 203, and a capping layer (910, CPL).

In addition, the light emitting element ED according to an embodiment of the present disclosure may be an organic light emitting device having a two-stack structure in which a first light emitting unit (1100) including a first organic light emitting layer and a second light emitting unit (1200) including a second organic light emitting layer are stacked between the first electrode 201 and the second electrode 203.

For example, in the light emitting element ED according to an embodiment of the present disclosure, the first light emitting unit or a first light emitting part 1100 may include a first organic light emitting layer consisting of a hole injection layer 820, a first hole transport layer 830, a first hole control layer 835, a first red emission layer 840, a first green emission layer 841 and a first blue emission layer 842, and a first electron transport layer 850.

In the light emitting element ED according to an embodiment of the present disclosure, the second light emitting unit or a second light emitting part 1200 may include a second organic light emitting layer consisting of a second hole transport layer 870, a second hole control layer 875, a second red emission layer 880, a second green emission layer 881 and a second blue emission layer 882, and a second electron transport layer 890.

The light emitting device according to an embodiment of the present disclosure may include a first charge generation layer 860, which is an n-type charge generation layer and a second charge generation layer 865, which is a p-type charge generation layer between the first light emitting unit 1100 and the second light emitting unit 1200.

In a display device including an organic light emitting device according to an embodiment of the present disclosure, there may be arranged a gate line and a data line which cross each other on the substrate to define each pixel area, and a power line which extends parallel to any one of the gate line and the data line in each pixel area. In addition, in each pixel area, there may be disposed a switching thin film transistor connected to the gate line and data line and a driving thin film transistor connected to the switching thin film. The driving thin film transistor may be connected to a first electrode 201.

The first electrode 201 may be located on the substrate to correspond to each of the red subpixel region (Rp), green subpixel region (Gp) and blue subpixel region (Bp), and may be made of a reflective electrode.

The hole injection layer 820 may be positioned on the first electrode 810 to correspond to all of the red subpixel region (Rp), green subpixel region (Gp) and blue subpixel region (Bp).

The hole injection layer 820 may facilitate hole injection, and may contain at least one of HATCN (1,4,5,8,9,11-hexaazatriphenylene-hexanitrile), CuPc (cupper phthalocyanine), PEDOT (poly(3,4)-ethylenedioxythiophene), PANI(polyaniline), and NDP(N,N-dinaphthyl-N,N′-diphenylbenzidine), but is not limited thereto.

The first hole transport layer 830 and the second hole transport layer 870 may be formed to correspond to all of the red subpixel area (Rp), green subpixel area (Gp), and blue subpixel area (Bp), respectively, The first hole transport layer 830 may be located on the hole injection layer 820, and the second hole transport layer 870 may be located on the second charge generation layer 865.

The first hole transport layer 830 and the second hole transport layer 870 may facilitate the transport of holes, and may contain at least one of NPD (N,N-dinaphthyl-N,N′-diphenylbenzidine), TDP (N,N′-bis-(3-methylphenyl)-N,N′-bis-(phenyl)-benzidine, s-TAD, and MTDATA (4,4′,4″-Tris(N-3-methylphenyl-N-phenyl-amino)-triphenylamine), but is not limited thereto.

In the light emitting element ED according to an embodiment of the present disclosure, the first hole control layer 835 may be positioned on the first hole transport layer 830 to correspond to all of the red subpixel area (Rp), green subpixel area (Gp) and blue subpixel area (Bp).

The second hole control layer 875 may be located on the second hole transport layer 870 to correspond to all of the red subpixel region (Rp), green subpixel region (Gp), and blue su-pixel region (Bp).

Since holes have higher mobility characteristics than electrons at high temperatures, the first hole control layer 835 and the second hole control layer 875 may prevent a phenomenon in which holes pass through a first organic light emitting layer including a first red emission layer 840, a first green emission layer 841 and a first blue emission layer 842 and a second organic light emitting layer including a second red emission layer 880, a second green emission layer 881 and a second blue emission 882, which are regions where electrons and holes recombine to emit light, and move to the first electron transport layer 850 and the second electron transport layer 890, thereby leaving the light emitting area. The first hole control layer 835 and the second hole control layer 875 may be made of a material such as carbazole derivative, triarylamine derivative, or triamine derivative. For example, the first hole control layer 835 and the second hole control layer 875 may be made of at least one of TPD (N,N′-Bis(3-methylphenyl)-N,N′-bis(phenyl)-benzidine), α-NPB(Bis[N-(1-naphthyl)-N-phenyl]benzidine), TDAPB (1,3,5-tris(4-diphenylaminophenyl)benzene), TCTA (Tris(4-carbazoyl-9-yl)triphenylamine), spiro-TAD(2,2′,7,7′-Tetrakis(N,N-diphenylamino)-9,9-spirobifluorene), CBP (4,4′-bis(carbazol-9-yl)biphenyl), BFA-IT(4-[bis(9,9-dimethylfluoren-2-yl)amino] phenyl group), spiro-TCBz (triclabendazole), and TBA, but is not limited thereto.

The first hole control layer 835 and the second hole control layer 875 may be made of the same material among the materials described above, and the holes in the first light-emitting unit 1100 and the second light-emitting unit 1200 Considering the mobility characteristics, it may be made of different materials among the materials described above. Alternatively, the first hole control layer 835 and the second hole control layer 875 may be made of different materials among the materials described above in consideration of the hole mobility characteristics in the first light emitting unit 1100 and the second light emitting unit 1200.

The first red emission layer 840 may be located in the red subpixel region (Rp) on the first hole transport layer 830, and the second red emission layer 880 may be located in the red subpixel region (Rp) on the second hole transport layer 870. The first red emission layer 840 and the second red emission layer 880 may each include a light emitting material emitting red light, and the light emitting material may be formed using a phosphorescent material or a fluorescent material.

As an example, the first red emission layer 840 and the second red emission layer 880 may contain a host material including CBP (4,4′-bis(carbozol-9-yl) biphenyl) or mCP (1,3-bis(N-carbozolyl)benzene), or may be made of a phosphorescent material containing a dopant including one or more of PQIr (acac) (bis (1-phenylquinoline) acetylacetonate iridium), PQIr (tris (1-phenylquinoline)iridium) and PtOEP (octaethylporphyrin platinum). Alternatively, the first red emission layer 840 and the second red emission layer 880 may be made of a fluorescent material containing PBD: Eu(DBM)3(Phen) or Perylene, but are not limited thereto.

The first green emission layer 841 may be located in the green subpixel region (Gp) on the first hole transport layer 830, and the second green emission layer 881 may be located in the green subpixel region (Gp) on the second hole transport layer 870. The first green emission layer 841 and the second green emission layer 881 may each include a light emitting material emitting green light, and the light emitting material may be formed using a phosphorescent material or a fluorescent material.

As an example, the first green emission layer 841 and the second green emission layer 881 may contain a host material including CBP or mCP, or may be made of a phosphorescent material containing a dopant materials such as iridium complex containing Ir(ppy)3(fac tris (2-phenylpyridinc)iridium). Alternatively, the first green emission layer 841 and the second green emission layer 881 may be made of a fluorescent material containing Alq3 (tris(8-hydroxyquinolino)aluminum), but are not limited thereto.

The first blue emission layer 842 may be located in the blue subpixel region (Bp) on the first hole transport layer 830, and the second blue emission layer 882 may be located in the blue subpixel region (Bp) on the second hole transport layer 870. The first blue emission layer 842 and the second blue emission layer 882 may each include a light emitting material emitting blue light, and the light emitting material may be formed using a phosphorescent material or a fluorescent material.

As an example, the first blue emission layer 842 and the second blue emission layer 882 may contain a host material including CBP or mCP, or may be made of a phosphorescent material containing a dopant materials containing (4,6-F2ppy)2Irpic, but are not limited thereto. In addition, the first blue emission layer 842 and the second blue emission layer 882 may be made of fluorescent substance containing any one of spiro-DPVBi, spiro-6P, distylbenzene (DSB), distrylarylene (DSA), PFO-based polymer, and PPV-based polymer, but are not limited thereto.

The first electron transport layer 850 may be located on the first red emission layer 840, the first green emission layer 841 and the first blue emission layer 842 to correspond to all of the red subpixel region (Rp), green subpixel region (Gp) and blue subpixel region (Bp). In addition, the second electron transport layer 890 may be located on the second red emission layer 880, the second green emission layer 881 and the second blue emission layer 882 to correspond to all of the red subpixel region (Rp), green subpixel region (Gp) and blue subpixel region (Bp).

The first electron transport layer 850 and the second electron transport layer 890 may transport and inject electrons, and the thickness of the first electron transport layer 850 and the second electron transport layer 890 may be adjusted considering electron transport characteristics.

The first electron transport layer 850 and the second electron transport layer 890 may facilitate the transport of electrons, and may made of at least one of Alq3 (tris (8-hydroxyquinolino)aluminum), PBD (2-(4-biphenylyl)-5-(4-tert-butylpheny)-1,3,4oxadiazole), TAZ, spiro-PBD, BA1q, and SA1q, but arenot limited thereto.

It is possible to additionally configure an electron injection layer (EIL) separately on the second electron transport layer 890.

The electron injection layer (EIL) may utilize Alq3 (tris(8-hydroxyquinolino)aluminum), PBD (2-(4-biphenylyl)-5-(4-tert-butylpheny)-1,3,4oxadiazole), TAZ, spiro-PBD, BA1q or SA1q, but is not limited thereto.

Here, the structure is not limited according to the embodiment of the present disclosure, there may be omitted at least one of the hole injection layer 820, the first hole transport layer 830, the second hole transport layer 870, the first electron transport layer 850, the second electron transport layer 890, and the electron injection layer (EIL). In addition, at least one of the first hole transport layer 830, the second hole transport layer 870, the first electron transport layer 850, the second electron transport layer 890 and the electron injection layer (EIL) may be e formed of two or more layers.

The first charge generation layer 860 may be located on the first electron transport layer 850 to correspond to all of the red subpixel region (Rp), green subpixel region (Gp) and blue subpixel region (Bp), and the second charge generation layer 865 may be located on the first charge generation layer 860 to correspond to all of the red subpixel region (Rp), green subpixel region (Gp) and blue subpixel region (Bp). The first charge generation layer 860 and the second charge generation layer 865 may have an NP junction structure.

Referring to FIG. 9, the first charge generation layer 860 and the second charge generation layer 865 may be located between the first light emitting unit 1100 and the second light emitting unit 1200. In addition, the first charge generation layer 860 and the second charge generation layer 865 may adjust the charge balance between the two light emitting units of the first light emitting unit 1100 and the second light emitting unit 1200.

The first charge generation layer 860 may serve as an n-type charge generation layer (n-CGL) which assists the injection of electrons into the first light emitting unit 1100 located below the first charge generation layer 860. The second charge generation layer 865 may serve as a p-type charge generation layer (p-CGL) which assists injection of holes into the second light emitting unit 1200 located on top of the second charge generation layer 865.

For example, the first charge generation layer 860, which is an n-type charge generation layer (n-CGL) for injecting electrons, may be made of an alkali metal, an alkali metal compound or an organic material acting as electron injectors, or a compound thereof. Additionally, the host material of the first charge generation layer 860 may be made of the same material as that of the first electron transport layer 850 and the second electron transport layer 890. For example, there may be composed of a mixed layer in which an organic material such as an anthracene derivative is doped with a dopant such as lithium (Li), but is not limited thereto.

The second charge generation layer 865 may be located on the first charge generation layer 860. The second charge generation layer 865 may function as a p-type charge generation layer (p-CGL) acting as a hole injectors, and the host material of the second charge generation layer 865 may be made of the same material as that of the first hole injection layer 820, the first hole transport layer 830 and the second hole transport layer 870. For example, the second charge generation layer 865 may be composed of a mixed layer in which organic materials such as HATCN (1,4,5,8,9,11-hexaazatriphenylene-hexanitrile), CuPc (cupper phthalocyanine) and TBAHA (tris (4-bromophenyl)aluminum hexacholroantimonate) are doped with p-type dopant, but is not limited thereto. In addition, the p-type dopant may be made of either F4-TCNQ or NDP-9, but is not limited thereto.

The second electrode 203 may be located on the second electron transport layer 890 to correspond to all of the red subpixel region (Rp), green subpixel region (Gp) and blue subpixel region (Bp). For example, the second electrode 203 may be made of an alloy of magnesium and silver (Mg: Ag), and may have transflective characteristics. For example, the light emitted from the organic light emitting layer may be displayed to the outside through the second electrode 203. Since the second electrode 203 has transflective characteristics, a part of the light may be directed to the first electrode 201 again.

In this way, due to a micro cavity effect in which repetitive reflection occurs between the first electrode 201 and the second electrode 203 acting as a reflective layer, the light may be repeatedly reflected within the cavity between the first electrode 201 and the second electrode 203, thereby increasing light efficiency.

In addition, it is possible to form the first electrode 201 as a transmission electrode and the second electrode 203 as a reflection electrode so that the light from the organic light emitting layer is displayed to the outside through the first electrode 201.

The capping layer 910 may be located on the second electrode 203. The capping layer 910 may increase the light extraction effect in the organic light emitting device. The capping layer 910 may be made of one of materials of a first hole transport layer 830, a second hole transport layer 870, a first electron transport layer 850, a second electron transport layer 890, and a host materials of a first red emission layer 840, a second red emission layer 880, a first green emission layer 841, a second green emission layer 881, a first blue emission layer 842, and the second blue emission layer 882, but are not limited thereto. Additionally, the capping layer 910 can be omitted.

Hereinafter, it will be described various configurations of a display device capable of preventing a decrease in luminance while limiting the viewing angle according to an embodiment of the present disclosure.

According to an embodiment of the present disclosure, a display device may further include a first electrode disposed on at least a portion of a first planarization layer and a second planarization layer, and the first electrode may include an inclined portion disposed on a first portion of the second planarization layer.

According to an embodiment of the present disclosure, the inclined portion may overlap with the second light emitting area.

According to an embodiment of the present disclosure, a maximum horizontal distance between the inclined portion may be less than or equal to a maximum width of a lens in the horizontal direction.

According to an embodiment of the present disclosure, a display device may include a first non-emission area located between the first light emitting area and the second light emitting area.

According to an embodiment of the present disclosure, the first non-emission area may overlap the lens.

According to an embodiment of the present disclosure, a display device may further include a blocking layer spaced apart below the lens and disposed in an area other than the second light emitting area.

According to an embodiment of the present disclosure, a separation distance between the blocking layers may be less than or equal to a maximum width of the lens in a horizontal direction.

According to an embodiment of the present disclosure, a display device may further include a metal layer disposed spaced apart between the lens and the blocking layer and disposed in an area other than the second light emitting area.

According to an embodiment of the present disclosure, a separation distance between the metal layers may be less than or equal to a maximum width of the lens in the horizontal direction.

According to an embodiment of the present disclosure, a display device may further include a first electrode disposed on at least a portion of the first planarization layer and the second planarization layer, and the first electrode may include an inclined portion disposed on a inclined first portion of the second planarization layer.

According to an embodiment of the present disclosure, a maximum horizontal distance between the inclined portions may be less than or equal to a maximum width of the lens in the horizontal direction.

According to an embodiment of the present disclosure, a display device may further include a blocking layer spaced apart below the lens and disposed in an area other than the second light emitting area.

According to an embodiment of the present disclosure, a separation distance between the blocking layers may be less than or equal to a maximum width of the lens in a horizontal direction.

According to an embodiment of the present disclosure, a display device may further include a metal layer disposed spaced apart between the lens and the blocking layer and disposed in an area other than the second light emitting area.

According to an embodiment of the present disclosure, a separation distance between the metal layers may be less than or equal to a maximum width of the lens in the horizontal direction.

According to an embodiment of the present disclosure, the metal layer may be formed of the same material as a touch electrode.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments shown, but is to be accorded the widest scope consistent with the claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate on which a plurality of subpixels is disposed, each of the plurality of subpixels including a first light emitting area and a second light emitting area adjacent to the first light emitting area;
a first planarization layer on the substrate;
a second planarization layer which is disposed on the first planarization layer, and is open in an area overlapping the first light emitting area, and includes a first portion inclined while overlapping with the second light emitting area and a second portion surrounding the first portion;
a bank layer which is located on the second planarization layer and is open in the first light emitting area; and
a lens which is located on the bank layer and disposed to at least partially overlap with an area including the first portion.

2. The display device of claim 1, further comprising a first electrode disposed on at least a partial area on the first planarization layer and the second planarization layer,
wherein the first electrode comprises an inclined portion disposed on the first portion of the second planarization layer.

3. The display device of claim 2, wherein the inclined portion overlaps with the second light emitting area.

4. The display device of claim 3, wherein a maximum horizontal distance between the inclined portion is less than or equal to a maximum width of the lens in a horizontal direction.

5. The display device of claim 1, further comprising a first non-emission area located between the first light emitting area and the second light emitting area.

6. The display device of claim 5, wherein the first non-emission area overlaps with the lens.

7. The display device of claim 1, further comprising a blocking layer disposed spaced apart below the lens and disposed in an area other than the second light emitting area.

8. The display device of claim 7, wherein a separation distance between the blocking layers is less than or equal to a maximum width of the lens in a horizontal direction.

9. The display device of claim 7, further comprising a metal layer disposed to be spaced apart between the lens and the blocking layer and disposed in an area other than the second light emitting area.

10. The display device of claim 9, wherein a separation distance between the metal layers is less than or equal to a maximum width of the lens in a horizontal direction.

11. The display device of claim 9, wherein the metal layer is formed of the same material as a touch electrode.

12. The display device of claim 1, wherein the first planarization layer and the second planarization layer are separate and distinct from each other.

13. A display device, comprising:
a first planarization layer on a substrate;
a second planarization layer which is disposed on the first planarization layer, and includes at least one opening area, and includes at least a portion having an inclined surface around the opening area;
a bank layer located on the second planarization layer; and
a lens located on the bank layer and disposed to overlap at least partially with an area including the portion having the inclined surface.

14. The display device of claim 13, further comprising a first electrode disposed on at least a partial area on the first planarization layer and the second planarization layer,
wherein the first electrode comprises an inclined portion disposed on the portion having the inclined surface of the second planarization layer.

15. The display device of claim 14, wherein a maximum horizontal distance between the inclined portions is less than or equal to a maximum width of the lens in a horizontal direction.

16. The display device of claim 13, further comprising a blocking layer disposed spaced apart below the lens and disposed in an area other than the second light emitting area.

17. The display device of claim 16, wherein a separation distance between the blocking layers is less than or equal to a maximum width of the lens in a horizontal direction.

18. The display device of claim 16, further comprising a metal layer disposed to be spaced apart between the lens and the blocking layer and disposed in an area other than the second light emitting area.

19. The display device of claim 18, wherein a separation distance between the metal layers is less than or equal to a maximum width of the lens in a horizontal direction.

20. The display device of claim 11, wherein the first planarization layer and the second planarization layer are separate and distinct from each other.

21. A display device, comprising:
a first planarization layer on a substrate, the first planarization layer having a first surface;
a second planarization layer on the first planarization layer, the second planarization layer having a first portion and a second portion opposite and facing the first portion, the first portion and the second portion being spaced apart from each other;
a light emitting element including a first electrode, a second electrode, and a light emitting layer between the first and second electrodes;
a bank layer on the first and second portions of the second planarization layer; and
a lens located on the bank layer, the lens overlaps the at least one of the first portion or the second portion of the second planarization layer.

22. The display device of claim 21, wherein the first electrode is on and contacts the first surface of the first planarization layer.

23. The display device of claim 21, wherein the first portion of the second planarization layer includes a first side surface and the second portion of the second planarization layer includes a second side surface opposite and facing the first side surface, and
wherein the first electrode is on and contacts the first side surface of the second planarization layer, the first surface of the first planarization layer, and the second side surface of the second planarization layer.

24. The display device of claim 21, wherein the light emitting layer is disposed between the first portion of the second planarization layer and the second portion of the second planarization layer and the light emitting layer is spaced apart from both first and second portions of the second planarization layer.

25. The display device of claim 21, wherein the display device includes a first light emitting area, a first non-emission area, and a second light emitting area from a plan view,
wherein the first portion of the second planarization layer includes a first side surface and the second portion of the second planarization layer includes a second side surface opposite and facing the first side surface,
wherein the first light emitting area overlaps with the light emitting layer from a plan view,
wherein the second light emitting area overlaps with the at least one of the first side surface of the first portion of the second planarization layer and the second side surface of the second portion of the second planarization layer, and
wherein the first non-emission area is disposed between the first light emitting area and the second light emitting area from a plan view.

26. The display device of claim 25, wherein the first non-emission area surrounds the first light emitting area, and the second light emitting area surrounds the first non-emission area from a plan view.
